(19) United States
(12) Patent Application Publication
(10) Pub. No.: US 2026/0287669 A1
(43) Pub. Date: Sep. 24, 2026

(54) METHOD AND APPARATUS FOR DETECTING BATTERY CELLS WITH WELDING DEFECTS

(71) Applicant: SAMSUNG SDI CO., LTD., Yongin-si (KR)

(72) Inventor: YUNJIN LEE, Yongin-si (KR)

(21) Appl. No.: 19/399,260

(22) Filed: Nov. 24, 2025

(30) Foreign Application Priority Data
Mar. 20, 2025 (KR) 10-2025-0036060

(51) Int. Cl. G01R 31/392; G01R 31/36; G01R 31/367; G01R 31/388; G01R 31/389; H01M 10/42; H01M 10/44

(52) U.S. Cl. CPC G01R 31/392; G01R 31/3648; G01R 31/367; G01R 31/388; G01R 31/389; H01M 10/4285; H01M 10/441

(57) ABSTRACT

Provided are a method and apparatus for detecting a battery cell with a welding defect. The method of detecting a battery cell with a welding defect includes obtaining a voltage value of each of a plurality of battery cells charged under a selected charging condition, calculating a threshold value based on the voltage values of the plurality of battery cells at an identified state of charge (SOC) and detecting a battery cell of the plurality of battery cells with a welding defect by comparing the voltage value of one or more of the plurality of battery cells at the identified SOC with the threshold value.

### CROSS-REFERENCE TO RELATED APPLICATION

This application is based on and claims priority under 35 USC § 119 to Korean Patent Application No. 10-2025-0036060, filed on, 20 Mar. 2025, in the Korean Intellectual Property Office, the disclosure of which is incorporated by reference herein in its entirety.

### BACKGROUND

### 1. Field

The disclosure relates to a method and apparatus for detecting a battery cell with a welding defect.

### 2. Description of the Related Art

A battery cell of a lithium secondary battery is configured as an electrode assembly in which positive and negative active materials are separated by a separator. Such a battery cell includes a positive tab extending from a positive plate and a negative tab extending from a negative plate, and these tabs are welded to either a positive lead or a negative lead. If a welding condition of a welded portion included in the battery cell is poor, there is a possibility of safety issues, such as battery performance degradation and ignition. It may be desirable, therefore, to detect a battery cell with a welding defect.

Individually determining whether there is a welding defect for each battery cell being manufactured by using separate detection equipment or providing a separate detection operation may reduce the efficiency of the secondary battery manufacturing process. Therefore, it may be desirable to improve the efficiency and accuracy of a method of detecting a battery cell with a welding defect.

The background art described above is information to improve understanding of the background of the disclosure and may include information that does not constitute prior art.

### SUMMARY

The disclosure provides a method and apparatus for detecting a battery cell with a welding defect. In some embodiments, the disclosure provides a computer-readable recording medium on which a program for executing the above method on a computer is recorded. The problems to be solved are not limited to the problems described above, and other problems may exist.

According to one aspect of the disclosure, there is provided a method of detecting a battery cell with a welding defect including obtaining a voltage value of each of a plurality of battery cells charged under a selected charging condition, calculating a threshold value based on the voltage values of the plurality of battery cells at an identified state of charge (SOC), and detecting a battery cell of the plurality of battery cells with a welding defect by comparing the voltage value of each of the plurality of battery cells at the identified SOC with the threshold value.

According to one aspect of the disclosure, there is provided a computer-readable recording medium on which a program for executing the method of the first aspect on a computer is recorded.

According to one aspect of the disclosure, there is provided an apparatus for detecting a battery cell with a welding defect including a memory in which at least one program is stored and a processor operating by executing the at least one program, wherein the processor is configured to obtain a voltage value of each of a plurality of battery cells charged under a selected charging condition, calculate a threshold value based on the voltage values of the plurality of battery cells at an identified SOC, and 1 compare the voltage value of each of the plurality of battery cells at the identified SOC with the threshold value.

In some embodiments, other methods and other systems for implementing the disclosure and computer-readable recording mediums storing a computer program for executing the methods may be further provided.

Other aspects, features and advantages than those described above will become apparent from the following drawings, claims and detailed description of the disclosure.

### BRIEF DESCRIPTION OF THE DRAWINGS

The above and other aspects, features, and advantages of certain embodiments of the disclosure will be more apparent from the following description taken in conjunction with the accompanying drawings in which:

FIG. 1 is block diagram of trays containing battery cells according to an embodiment;

FIG. 2A is a graph of voltage behavior of a battery cell obtained during a charging process according to an embodiment;

FIG. 2B is a graph of voltage behavior of a battery cell in a second SOC section and a third SOC section obtained during a charging process according to an embodiment;

FIG. 2C is a graph of voltage behavior of a battery cell in a first SOC section obtained during a charging process according to an embodiment;

FIG. 3 is a flowchart of a method for detecting a battery cell with a welding defect according to an embodiment;

FIG. 4 is a flowchart illustrating a method for determining a cause of a failure of a battery cell exhibiting abnormal voltage behavior according to an embodiment;

FIG. 5 is a block diagram of a detection apparatus according to an embodiment.

### DETAILED DESCRIPTION

The advantages and features of the disclosure and the methods of achieving them will become apparent by reference to the embodiments described in detail together with the accompanying drawings. However, the disclosure is not limited to the embodiments presented below but may be implemented in various different forms and should be understood to include all transformations, equivalents, or substitutes included in the spirit and technical scope of the disclosure. The embodiments set forth below are provided to make this disclosure complete and to fully convey the scope of the disclosure to those skilled in the art to which the disclosure pertains. In describing the disclosure, if a detailed description of a related known art is determined to obscure the gist of the disclosure, the detailed description will be omitted.

The terminology used herein is for the purpose of describing particular embodiments only and is not intended to limit the disclosure. Unless otherwise defined, all terms used herein have the same meaning as commonly understood by one of ordinary skill in the art to which this disclosure pertains.

In this specification, singular expressions include plural expressions unless the context clearly indicates otherwise. Furthermore, it should be understood that terms, such as “include” or “have” are intended to specify the presence of a feature, number, step, operation, component, part, or combinations thereof described in the specification but do not exclude in advance the possibility of the presence or addition of one or more other features, numbers, steps, operations, components, parts, or combinations thereof.

In addition, terms including ordinal numbers, such as “first” or “second,” used herein may be used to describe various components, but the components should not be limited by the terms. The terms are used solely to distinguish one component from another.

The phrases, such as “in an embodiment,” “according to an embodiment,” “relating to an embodiment,” or “according to an implementation of an embodiment” in this specification are not necessarily all referring to the same embodiment. In addition, throughout the specification, the term “embodiment” is an arbitrary distinction used to facilitate the description of the disclosure, and each embodiment is not necessarily exclusive of the others. For example, components mentioned for the purpose of describing an embodiment may be applied and/or implemented in other embodiments and may be applied and/or implemented with modifications without departing from the scope of the disclosure.

References to two compared elements, features, etc. as being “the same” may mean that they are “substantially the same”. Thus, the phrase “substantially the same” may include a case having a deviation that is considered low in the art, for example, a deviation of 5% or less.

Some embodiments of the disclosure may be represented by functional block components and various processing steps. Some or all of these functional blocks may be implemented with any number of hardware and/or software components that perform specific functions. For example, the functional blocks of the disclosure may be implemented by one or more microprocessors or by circuit components for a given function.

In addition, for example, the functional blocks of the disclosure may be implemented in various programming or scripting languages. Functional blocks may be implemented as algorithms that run on one or more processors. In addition, the disclosure may employ related arts for electronic environment setting, signal processing, and/or data processing. Terms, such as “mechanism,” “element,” “unit,” and “component” may be used broadly and are not limited to mechanical and physical components. In addition, terms, such as “-portion,” “-module,” etc. refer to a unit that processes at least one function or operation, which may be implemented by hardware, firmware, or software or by a combination of hardware, firmware, and software.

In addition, some components in the drawing may have been exaggerated in size or proportion for convenience of description.

Hereinafter, the disclosure is described in detail with reference to the accompanying drawings.

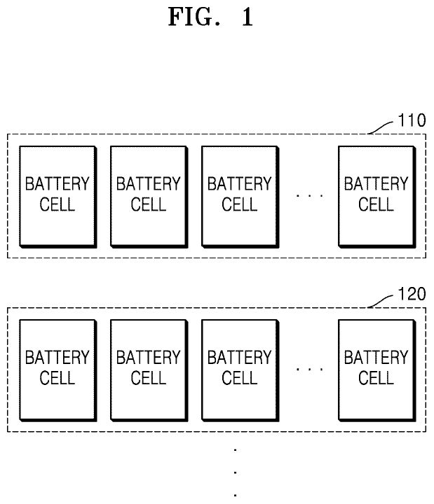

FIG. 1 is block diagram of trays containing battery cells according to an embodiment.

Referring to FIG. 1, a first tray 110 including a plurality of battery cells and a second tray 120 including a plurality of battery cells are illustrated.

The process of manufacturing a secondary battery may include an assembly process of assembling battery cell components including a positive electrode, a negative electrode, a separator, an electrolyte, and an outer casing. The assembled battery cell may include a positive tab extending from a positive plate and a negative tab extending from a negative plate, and the positive tab and the negative tab may be welded to a positive lead or a negative lead, respectively.

If a welding condition of the battery cell is poor, such as, for example, if welding is performed weaker than reference strength, the charge/discharge efficiency of the battery cell may decrease or the stability of the battery cell may decrease due to increased contact resistance.

The manufacturing process of the secondary battery may include a formation process inducing a chemical reaction between an electrode and an electrolyte by performing charging and discharging on the assembled battery cell. In the formation process, information, such as voltage, current, and resistance of the battery cell may be obtained according to the charging and discharging of the battery cell.

In the disclosure, “voltage of a battery cell” may refer to a terminal voltage of a battery cell that changes due to a chemical reaction and current flow inside the cell. In addition, “charge voltage” and “charge current” may refer to voltage and current applied to a battery cell, respectively, to charge the battery cell. In addition, “charging condition” may refer to a concept including charging voltage, charging current, charging speed, and charging profiles applied to a battery cell to perform charging of the battery cell.

Referring to FIG. 1, the first tray 110 and the second tray 120 may each include a plurality of battery cells. In some embodiments, the trays may include a structure for performing charging and discharging of a plurality of battery cells at once. Int his regard, the plurality of battery cells may be concurrently charged.

In an embodiment, charging and discharging of battery cells may be performed in units of battery trays including an identified or a preset number of battery cells. In this case, a plurality of battery cells included in one tray may be charged under one or more selected (e.g., the same) charging conditions.

For example, a detection apparatus may control the charging conditions so that the same charging voltage or charging current is applied to the plurality of battery cells included in the first tray 110. In some embodiments, the detection apparatus may control the charging conditions so that the plurality of battery cells included in the first tray 110 are charged at the same charging speed or charging profile. In some embodiments, the detection apparatus may control the charging conditions so that the same charging voltage or charging current is applied to both the plurality of battery cells included in the first tray 110 and the plurality of battery cells included in the second tray 120. In some embodiments, the detection apparatus may control the charging conditions by transmitting a control signal to a charging/discharging device included in a manufacturing device of the battery cell so that a plurality of battery cells are applied with the same charging voltage or charging current.

In some embodiments, information, such as voltage, current, and resistance of a battery cell may be individually collected for one or more (e.g., each) of a plurality of battery cells included in a tray. For example, the detection apparatus may receive sensing information on voltage, current, and resistance collected for one or more (e.g., each) of a plurality of battery cells. In some embodiments, the detection apparatus may obtain a voltage value of one or more (e.g., each) of the plurality of battery cells included in the first tray 110 and the second tray 120.

In some embodiments, a charging process of the battery cells may be performed on an individual battery cell basis. Even in this embodiment, one or more (e.g., each) battery cell may be charged under the same charging conditions. In some embodiments, the detection apparatus may obtain a charge voltage value of one or more (e.g., each) battery cell.

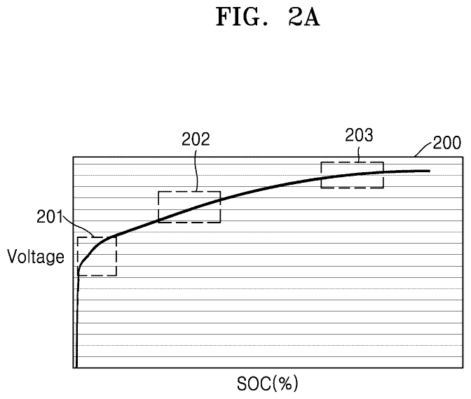

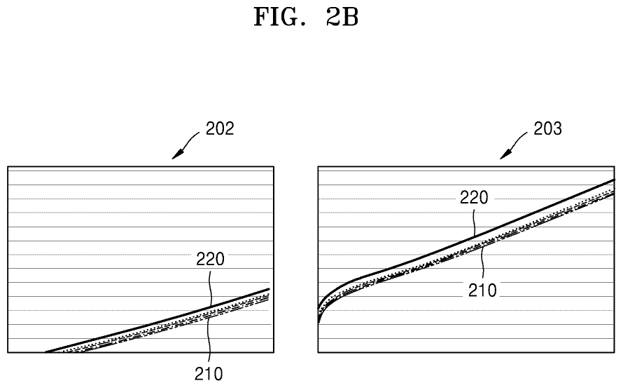

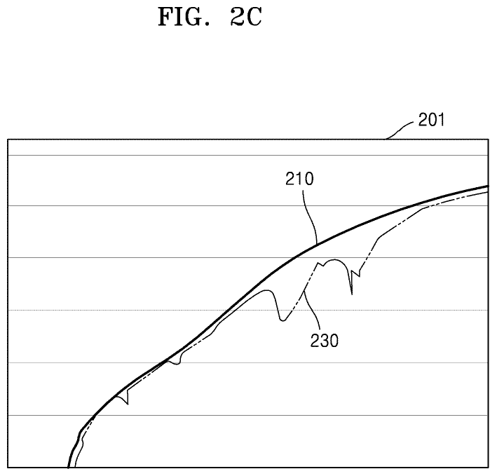

FIG. 2A is a graph of voltage behavior of a battery cell obtained during a charging process according to an embodiment.

The graph of FIG. 2A depicts a graph of voltage values according to a state of charge (SOC) of battery cells when a plurality of battery cells are charged under the same charging conditions. In some embodiments, the SOC is an indicator of a state of charge of a battery cell and may refer to the ratio of a currently charged capacity to a maximum charge capacity of the battery. In some embodiments, a voltage refers to a voltage value of a battery cell measured at a terminal during a charging process of the battery cell and may refer to a value determined by a charging current or charging voltage applied to the battery cell, internal resistance of the battery cell, SOC, etc.

As illustrated in FIG. 2A, when a charging current or charging voltage is applied to a battery cell, a voltage value of the battery cell tends to gradually increase as the SOC of the battery cell increases.

In some embodiments, even if the same charging current or charging voltage is applied to a plurality of battery cells, respective voltage values of the plurality of 1 battery cells may be different. For example, due to variations occurring in the assembly process of one or more (e.g., each) battery cell, internal resistance values of the battery cells may differ for the battery cell, and accordingly, the voltage values of the battery cells may also differ for the battery cell. As an example, a battery cell with a welding defect has higher internal resistance value than a normal battery cell, and therefore, the battery cell with a welding defect tends to exhibit a higher voltage than a normal battery cell (e.g., a battery cell without the welding defect).

In another example, if contact between a terminal of a battery cell and a charge/discharge terminal is poor, such a poor-contact battery cell exhibits abnormal voltage behavior compared to a normal battery cell.

In some embodiments, a difference in voltage behavior of a plurality of battery cells when the same charging current or charging voltage is applied may exhibit a certain pattern due to the aforementioned cause of defects in the battery cells and the SOC of the battery cells.

In this regard, referring to FIG. 2A, a graph 200 regarding voltage behavior of a battery cell in the entire SOC section may include a graph 201 regarding voltage behavior of a battery cell in a first SOC section, a graph 202 regarding voltage behavior of a battery cell in a second SOC section, and a graph 203 regarding voltage behavior of a battery cell in a third SOC section. Hereinafter, voltage behaviors of a normal battery cell, a battery cell with a welding defect, and a poor-contact battery cell in the first SOC section, the second SOC section, and the third SOC section are described with reference to FIGS. 2B and 2C.

FIG. 2B is a graph of voltage behavior of a battery cell in the second SOC section and the third SOC section obtained during a charging process according to an embodiment.

Referring to FIG. 2B, the graph 202 regarding voltage behavior of a normal battery cell and a battery cell with a welding defect in the second SOC section and the 1 graph 203 regarding voltage behavior of the normal battery cell and the battery cell with a welding defect in the third SOC section are illustrated.

In some embodiments, the second SOC section and the third SOC section refer to certain sections regarding the SOC of the battery. In an embodiment, the third

SOC section may be defined as a certain section in which the voltage of the battery cell with a welding defect and the voltage of the normal battery cell show a difference equal to or greater than a certain value. Also, the second SOC section may be defined as a certain section including a lower value of SOC compared to the third SOC section.

Referring to FIG. 2B, the graph 202 and the graph 203 include a voltage behavior curve 210 of the normal battery cell and a voltage behavior curve 220 of the battery cell with a welding defect. As described above, the internal resistance value of the battery cell with a poor welding condition may show a difference (e.g., a significant difference) in relationship with the internal resistance value of the battery cell with a normal welding condition. In some embodiments, under the same charging conditions, the battery cell with a poor welding condition (hereinafter, a battery cell with a welding defect) may show a different voltage behavior from the battery cell with a normal welding condition (e.g., a welding condition without a welding defect).

For example, referring to the graph 202 and the graph 203, the voltage behavior curve 220 of the battery cell with a welding defect shows a higher voltage value compared to the voltage behavior curve 210 of the normal battery cell. In some embodiments, the difference between the voltage value of the battery cell with a welding defect and the voltage value of the normal battery cell tends to increase or become more severe as the SOC of the battery cells increases.

Table 1 shows specific experimental data regarding measured values of battery cell voltages obtained from an SOC (30%) randomly selected from the second SOC section and SOC (70%) randomly selected from the third SOC section. In some embodiments, Table 1 is a table showing voltage measurement values of the battery cells included in a tray obtained from the selected SOCs (30% and 70%) after performing charging for the tray including 100 battery cells using an NCM active material.

Also, in Table 1, V_{median} denotes the median of the voltage values measured for all battery cells included in a certain tray, and Va denotes the voltage value measured for a battery cell with a welding defect included in the corresponding tray. Also, AV denotes a difference value between V_{median} and V_{d}.

TABLE 1

| | V_{median} | V_{d} | ΔV | ΔV |
|---|---|---|---|---|
| | (mV) | (mV) | (mV) | (%) |
| 30% SOC | 3717.2 | 3729 | 11.8 | 0.32 |
| 70% SOC | 3874.7 | 3890.1 | 15.4 | 0.40 |

Referring to Table 1, at 30% SOC, the battery cell with a welding defect showed a voltage that was 11.8 mV higher than the median voltage value of all battery cells, and at 70% SOC, the battery cell with a welding defect showed a voltage that was 15.4 mV higher than the median voltage value of all battery cells.

In some embodiments, referring to FIG. 2B and Table 1, it can be seen that the difference in the voltage values between the battery cell with a welding defect and the normal battery cell is greater in the third SOC section compared the second SOC section.

FIG. 2C is a graph 201 of voltage behavior of a battery cell in the first SOC section obtained during a charging process according to an embodiment.

The graph 201 of FIG. 2C depicts the voltage behavior of the normal battery cell and a poor-contact battery cell in the first SOC section.

In some embodiments, the first SOC section is a certain section regarding the SOC of the battery, and in an embodiment, the first SOC section may be defined as a certain section in which a chemical reaction of a battery cell is activated and a voltage of the battery cell increases at a slope equal to or greater than a certain value.

The graph 201 includes the voltage behavior curve 210 of the normal battery cell and a voltage behavior curve 230 of the poor-contact battery cell. As shown in FIG. 2C, the voltage behavior curve 230 of the poor-contact battery cell shows a more irregular voltage increase slope and a greater voltage value deviation in the first SOC section compared to the voltage behavior curve 210 of the normal battery cell. The voltage behavior curve 230 of the poor-contact battery cell may also exhibit irregular voltage spikes and vibration patterns compared to the normal battery cell.

In some embodiments, referring to FIG. 2C, it can be seen that there is a tendency for the voltage behavior of a poor-contact battery cell to be different (e.g., significantly different) from the voltage behavior of a normal battery cell in the first SOC section.

A method of detecting a battery cell with a welding defect according to an embodiment of the disclosure may be based on the voltage behavior characteristics of the poor-contact battery cell in the first SOC section and/or the voltage behavior characteristics of the battery cell with a welding defect in the third SOC section, as described above with reference to FIGS. 2A to 2C.

Also, the first to third SOC sections described above with reference to FIGS. 2A to 2C may refer to sections determined based on user monitoring of voltage behaviors of the normal battery cell, the battery cell with a welding defect, and the poor-contact battery cells. In some embodiments, the user may determine a certain section in which the voltage behavior characteristics unique to the poor-contact battery cell are severe (e.g., above a threshold) during the charging process of the battery cell as the first SOC section and may determine a certain section in which the voltage behavior characteristics unique to the battery cell with a welding defect are severe (e.g., above a threshold) as the third SOC section.

For example, by monitoring the voltage value during the charging process of the battery cell, the user may determine the first SOC section as a section in which the SOC of the battery is 20% or less and the third SOC section as a section in which the SOC of the battery exceeds 70%. For another example, the first SOC section may be determined as a section in which the SOC of the battery is 10% or less, and the third SOC section may be determined as a section in which the SOC of the battery exceeds 80%, and so on. As another example, the first SOC section may be determined as a section in which the SOC of the battery is 5% or less, the third SOC section may be determined as a section in which the SOC of the battery exceeds 85%, and so on.

However, the specific numerical ranges for the first SOC section and the third SOC section described above are merely examples and are not limited to the above. In other words, the first to third SOC sections may be determined to be different depending on the environment in which the disclosure is implemented (e.g., the type of battery cell, characteristics of the battery manufacturing process or equipment, charging protocol, etc.).

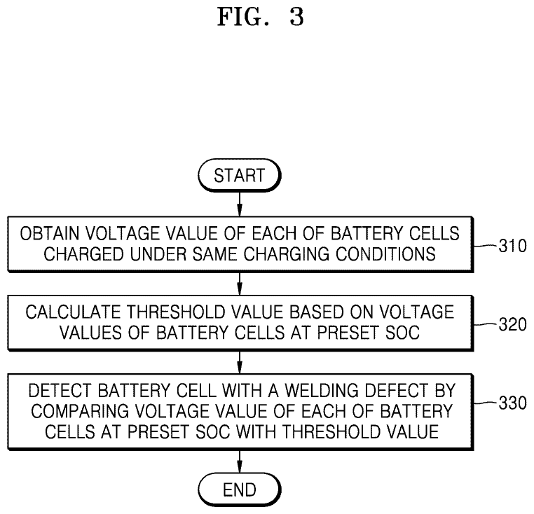

FIG. 3 is a flowchart of a method of detecting a battery cell with a welding defect according to an embodiment.

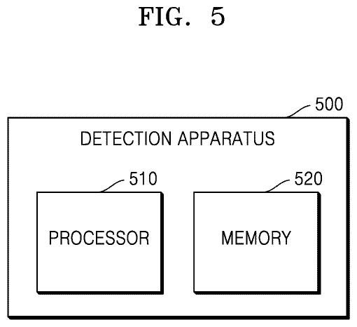

The method of detecting a battery cell with a welding defect described above with reference to FIG. 3 may be performed by a detection apparatus of FIG. 5 and specifically may be performed by a processor included in the detection apparatus. In operation 310, the processor may obtain voltage values of one or more

(e.g., each) of a plurality of battery cells charged under a selected (e.g., the same) charging condition. In some embodiments, the charging condition may refer to a condition regarding a charging parameter, such as a charging voltage, a charging current, a charging speed, and/or a charging profile applied to the battery cell to perform charging of the battery cell, as described above.

In an embodiment, the detection apparatus may obtain voltage values collected (e.g., individually collected) for one or more (e.g., each) of the plurality of battery cells. For example, the detection apparatus may receive a voltage value from a voltage sensor.

In operation 320, the processor may calculate a threshold value based on voltage values of a plurality of battery cells at an identified (e.g., a preset) SOC.

In an embodiment, the preset SOC may be input into the detection apparatus by the user so as to be set. For example, the user may input an input value regarding an SOC into the detection apparatus to detect a battery cell with a welding defect based on the voltage value of the battery cell when the SOC is 70%. In this case, the processor may calculate a threshold value, based on voltage values of a plurality of battery cells at the input SOC.

In some embodiments, the user may determine the SOC to be input into the detection apparatus based on a statistical analysis of the relationship between a voltage distribution of the battery cell with a welding defect and the SOC. For example, the user may determine an SOC that is effective (e.g., most effective) for detecting a battery cell with a welding defect by statistically/empirically analyzing the difference in voltage values between the battery cell with a welding defect and the normal battery cell, at the preset SOC described above.

In some embodiments, as described above with reference to FIGS. 2A to 2C, the battery cell with a welding defect has a characteristic of exhibiting a higher voltage than that of the normal battery cell, and this characteristic may increase or tends to become more severe in the third SOC section. Accordingly, in an embodiment, the preset SOC may be selected by the user from within the third SOC described above, and the processor may set the preset SOC based on the user input regarding the first SOC and the second SOC.

In an embodiment, the processor may calculate the threshold value based on statistical values of voltage values of a plurality of battery cells at the preset SOC. In some embodiments, the processor may calculate a threshold value for detection of the 1 battery cell with a welding defect based on at least one statistical value of a mean, a median, a variance, a standard deviation, and a quartile of voltage values of a plurality of battery cells.

In some embodiments, the processor may utilize a sensitivity factor for adjusting the detection sensitivity of the battery cell with a welding defect to calculate the threshold value. In some embodiments, the sensitivity factor may be input by the user into the detection apparatus to be set. In this regard, the user may analyze the accuracy of the battery cell with a welding defect detected by the detection apparatus to determine a sensitivity factor to be input into the detection apparatus.

An equation for calculating a threshold value according to an embodiment may be expressed as Equation 1 below. In Equation 1, V_{T}, Q3, IQR, and a represent a threshold value that may be determined as a normal battery cell, the third quartile of the voltage values of all battery cells, a difference value between the third quartile and the first quartile of the voltage values of all battery cells, and a sensitivity factor, respectively. In some embodiments, VT, Q3, and IQR may be calculated based on the voltage values of the battery cells obtained at the preset SOC.

$${V}_{T} = {Q}_{3} + I Q R \times a \qquad Equation 1$$

In some embodiments, the processor may calculate a first threshold value based on voltage values of a plurality of battery cells at a first SOC and may calculate a second threshold value based on voltage values of a plurality of battery cells at a second SOC. In some embodiments, the first SOC and the second SOC may be set based on user input.

In this regard, the user may determine a SOC to be input to the detection apparatus based on a statistical analysis of the relationship between a voltage distribution of the battery cell with a welding defect and the SOC, as described above. For example, the user may statistically/empirically analyze the difference in voltage values between the battery cell with a welding defect and the normal battery cell and determine an SOC that is effective (e.g., is most effective) for detecting the battery cell with a welding defect, as the first and second preset SOCs.

In some embodiments, as described above with reference to FIGS. 2A to 2C, the battery cell with a welding defect has a characteristic of exhibiting a higher voltage than that of the normal battery cell, and this characteristic tends to become more severe in the third SOC section. In some embodiments, the poor-contact battery cell has the characteristics of exhibiting a lower voltage than that of the normal battery cell or an irregular voltage spike and vibration pattern, and these characteristics tend to be severe or increase in the first SOC section.

Accordingly, in an embodiment, the first SOC and the second SOC may be selected by the user within the first SOC section and a third SOC section, respectively, and the processor may set the first SOC and the second SOC based on user input regarding the first SOC and the second SOC.

In an example, it is assumed that the first SOC section is determined as a section of SOC 20% or less and the third SOC section is determined as a section of SOC 80% or more, based on the user's monitoring of the voltage behaviors of the normal battery cell, the battery cell with a welding defect, and the poor-contact battery cell. In this case, in order to distinguish between voltage behavior abnormalities due to poor contact and voltage behavior abnormalities due to a welding defect, the user may select and set the first SOC to “SOC 10%” belonging to the first SOC section and the second SOC to “SOC 85%” belonging to the third SOC section, but is not limited thereto.

The processor may calculate a first threshold value based on a difference between the voltage behavior of the poor-contact battery cell and the voltage behavior of the normal battery cell at the first SOC. Similarly, the processor may calculate a second threshold value based on a difference between the voltage behavior of the battery cell with a welding defect and the voltage behavior of the normal battery cell at the second SOC.

In some embodiments, as described above with reference to FIGS. 2A to 2C, a battery cell whose voltage value at the first SOC exceeds the first threshold value is likely to have exhibited abnormal voltage behavior due to a cause other than a welding defect, such as poor contact. In some embodiments, a battery cell whose voltage value at the second SOC exceeds the second threshold is likely to have exhibited abnormal voltage behavior due to a welding defect. Therefore, according to the above-described embodiment, abnormal behavior of a battery cell voltage due to a welding defect and abnormal behavior of a battery cell voltage due to other defect causes, such as poor contact, may be distinguished from each other.

In operation 330, the processor may detect the battery cell with a welding defect by comparing the voltage value of one or more (e.g., each) of the plurality of battery cells at a preset SOC with a threshold value.

In an embodiment, if the voltage value of the battery cell at the preset SOC exceeds the threshold value, the processor may detect the battery cell as a battery cell with a welding defect.

In an embodiment, the processor may detect the battery cell with a welding defect, based on voltage values of the battery cell at the first SOC and the second SOC and the first threshold value and the second threshold value. For example, the processor may detect a battery cell having a voltage value at the first SOC not exceeding (e.g., lower than) the first threshold value and a voltage value at the second SOC exceeding the second threshold value, as a battery cell with a welding defect. As another example, the processor may detect a battery cell having a voltage value at the first SOC exceeding the first threshold value and a voltage value at the second SOC exceeding the second threshold value, as a battery cell with a welding defect.

In some embodiments, the processor may output the result of the detection of battery cells with a welding defect to a user. To this end, the detection apparatus may include a user interface unit for performing interaction with the user, and the detection result may be output to the user through the user interface unit (e.g., a display). Accordingly, the user may be informed in advance of a battery cell with a welding defect during the monitoring process of the charge/discharge operation and may discard or repair the defective battery cell.

Meanwhile, as described above, the processor of the detection apparatus may control the charging/discharging of at least some of the battery cells by controlling a device that performs battery charging/discharging. For example, the detection apparatus may be a physically separate device from the device that performs battery charging/discharging (e.g., a Charger, a Power Supply, or a Battery Management System (BMS), etc.). In this case, the processor of the detection apparatus can control the battery charging/discharging by transmitting a control signal to the device that performs the battery charging/discharging. In another example, the detection apparatus and the device that performs the battery charging/discharging may be physically implemented as a single device (e.g., a BMS, etc.). In this case, the processor of the detection apparatus can cut off or adjust the current flow to at least some of the battery cells (or packs or trays) by directly driving or controlling an internal control circuit.

In this regard, in some embodiment, the processor of the detection apparatus can control the charging/discharging of at least some of the battery cells based on the detection result of a battery cell with a welding defect. For example, the processor of the detection apparatus may control the battery charging/discharging such that the charging/discharging for the detected cell is stopped in response to the detection of the battery cell with the welding defect. In another example, the processor of the detection apparatus may control the battery b charging/discharging such that the charging/discharging for the entire battery cells including the detected cell is stopped in response to the detection of the battery cell with the welding defect.

In some embodiments, the detection apparatus may further perform an operation of determining the cause of a defect in a battery cell determined to be the battery cell with a welding defect according to operations 310 to 330 described above.

In an embodiment, the processor may select the battery cell determined to be the battery cell with a welding defect as a candidate cell of a welding defect according to operations 310 to 330 and may obtain a weld image of the candidate cell of a welding defect. In some embodiments, the processor may detect a battery cell with a welding defect based on information included in the weld image of the candidate cell of a welding defect. In some embodiments, the information included in the weld image may include weld conditions, such as a weld length, a weld width, and whether there is a crack included in the image.

In some embodiments, the processor may perform an operation to output the weld image of the candidate cell of a welding defect to the user. In this case, the user may analyze the weld image to check whether the determination of whether there is a welding defect as determined by the detection apparatus is accurate. In some embodiments, the candidate cell with the welding defect may be replaced or repaired, resulting in an improved secondary battery.

In some embodiments, the processor may select a battery cell determined to be the battery cell with a welding defect according to operations 310 to 330 as a candidate cell of a welding defect and detect the battery cell with a welding defect based on a DC resistance value of the candidate cell of a welding defect. In some embodiments, the DC resistance value of the candidate cell of a welding defect may be calculated based on a DC current value applied to the cell. For example, the processor may detect the battery cell with a welding defect based on a characteristic regarding the DC resistance value of the battery cell with a welding defect.

In some embodiments, the processor may select a battery cell determined to be the battery cell with a welding defect according to operations 310 to 330 as a candidate cell of a welding defect and detect the battery cell with a welding defect based on an AC impedance value of the candidate cell of a welding defect. In some embodiments, the AC impedance value of a candidate cell of a welding defect may be calculated based on the AC current value applied to the cell. For example, the processor may detect the battery cell with a welding defect based on characteristics of the AC impedance value of the battery cell with a welding defect.

In some embodiments, all or some of the operations according to operations 310 to 330 described above may be performed independently for each battery tray including a preset number of battery cells.

For example, the processor may obtain a voltage value of one or more (e.g., each) of a plurality of battery cells included in a first tray and calculate a threshold value based on the voltage values of the plurality of battery cells included in the first tray at a preset SOC. Also, the processor may compare the voltage value of one or more (e.g., each) of the plurality of battery cells included in the first tray with a threshold value at the preset SOC and detect a battery cell with a welding defect among the plurality of battery cells included in the first tray. In conjunction with this, or sequentially, the processor may perform the aforementioned operations on a plurality of battery cells included in the second tray. In this case, the threshold value calculated for the first tray and a threshold value calculated for the second tray are calculated independently and may be the same or different from each other.

A plurality of battery cells included in the same tray are charged in the same environment (e.g., the same facility or the same space). In some embodiments, when a plurality of battery cells included in the same tray exhibit different charging voltage behaviors, it may be determined that a difference in charging voltage behavior is not due to the charging environment. Therefore, according to the above-described 1 embodiment, a possibility that an abnormal voltage behavior of a certain battery cell caused by a charging environment is erroneously determined as being caused by a welding defect may be reduced.

In some embodiments, with respect to FIG. 3, for convenience of description, a process of detecting the battery cell with a welding defect based on one or two SOCs and one or two threshold values has been described, but the disclosure is not limited thereto. In other words, the process of detecting the battery cell with a welding defect according to the disclosure may be performed based on three or more SOC sections and three or more threshold values.

In some embodiments, the specific numerical values regarding the first SOC and the second SOC described above with reference to FIG. 3 are merely examples and are not limited to the above. In other words, the first and second SOCs may be determined to be different depending on the environment in which the disclosure is implemented (e.g., the type of battery cell, characteristics of the battery manufacturing process or equipment, charging protocol, etc.).

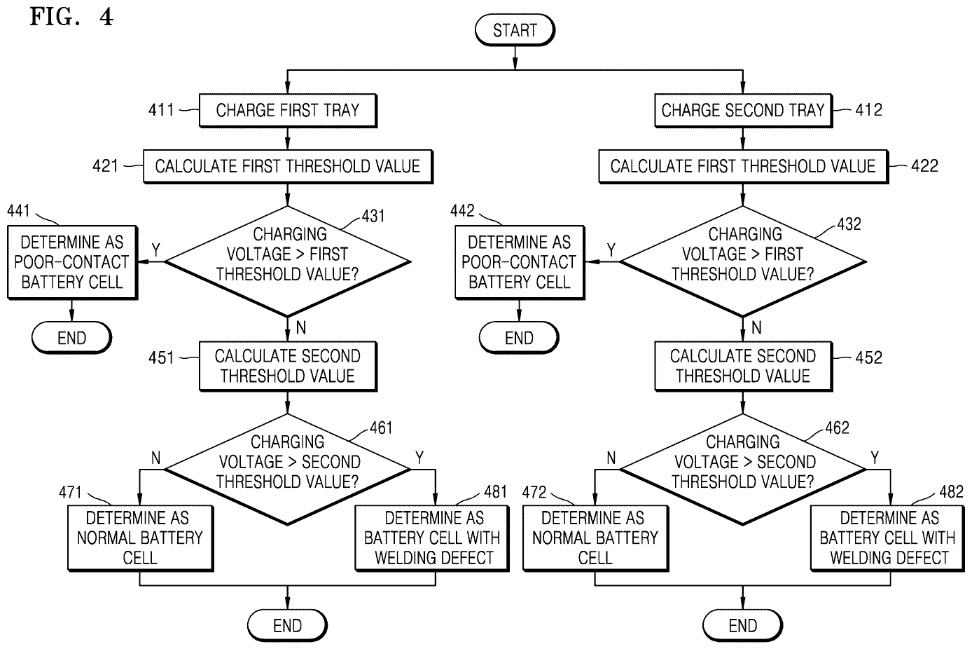

FIG. 4 is a flowchart of a method for determining a cause of a defect of a battery cell exhibiting abnormal voltage behavior according to an embodiment.

The method for determining a cause of a defect in a battery cell exhibiting abnormal voltage behavior as described above with reference to FIG. 4 may be performed by the detection apparatus of FIG. 5, for example, by a processor included in the detection apparatus.

In operation 411, the processor may control a plurality of battery cells included in the first tray to be charged under the same charging conditions.

In operation 421, the processor may calculate a first threshold value. In some embodiments, the first threshold value may be calculated based on voltage values of battery cells at the first SOC.

In operations 431 and 441, the processor may compare, for one or more (e.g., each) of the plurality of battery cells included in the first tray, a voltage value of the battery cell at the first SOC with a first threshold value. For example, the processor may determine or identify a battery cell having a voltage value at the first SOC exceeding the first threshold value as a poor-contact battery cell. Also, the detection apparatus may output information on a target battery cell and a determination result to the user.

In operation 451, the processor may calculate a second threshold value. In some embodiments, the second threshold value may be calculated based on the voltage values of the battery cells at the second SOC.

In operations 461, 471, and 481, the processor may compare, for one or more (e.g., each) of the plurality of battery cells included in the first tray, a voltage value of the battery cell at the second SOC with a second threshold value. For example, the processor may determine or identify a battery cell having a voltage value at the second SOC exceeding the second threshold value as a battery cell with a welding defect. In some embodiments, the processor may determine or identify a battery cell having a voltage value at the second SOC below the second threshold value as a normal battery cell. Also, the detection apparatus may output information on the target battery cell and the determination result to the user.

In some embodiments, the processor may perform operations 411 to 481 described above on a plurality of battery cells included in the second tray in operations 412 to 482.

In some embodiments, the processor may control a plurality of battery cells included in the second tray to be charged under the same charging conditions.

Further, the processor may calculate a first threshold value and compare a voltage value of a battery cell at a first SOC for one or more (e.g., each) of a plurality of battery cells included in the second tray with the first threshold value.

In some embodiments, the processor may calculate a second threshold value and compare a voltage value of a battery cell at a second SOC for one or more (e.g., each) of the plurality of battery cells included in the second tray with the second threshold value.

In some embodiments, the first and second threshold values calculated for the first tray and the first and second threshold values calculated for the second tray are calculated independently and may have different values.

In some embodiments, for convenience of description, FIG. 4 illustrates a process of detecting a battery cell with a welding defect performed on two trays and a process of detecting a battery cell with a welding defect performed based on two SOCs and two threshold values, but the disclosure is not limited thereto. In other words, all or some of the operations of the detection apparatus described above may be performed for more or fewer trays and for more or fewer SOCs.

FIG. 5 is a block diagram of a detection apparatus 500 according to an embodiment.

Referring to FIG. 5, the detection apparatus 500 may include a processor 510 and a memory 520. Only components related to the embodiment are shown in the detection apparatus 500 of FIG. 5. Accordingly, it will be understood by those skilled in the art that other general components may be included in addition to the components illustrated in FIG. 5. For example, although not shown in FIG. 5, the detection apparatus 500 may include a communication unit for receiving voltage sensing information of a battery cell and an interface unit for enabling interaction with a user.

The processor 510 controls the overall operation of the detection apparatus 500. For example, the processor 510 may control the components included in the detection apparatus 500 overall by executing programs stored in the memory 520. In some embodiments, the processor 510 may control the operation of the detection apparatus 500 by executing programs stored in the memory 520.

The processor 510 may control at least some of the operations of the detection apparatus 500 described above with reference to FIGS. 1 to 4. For example, the processor 510 may obtain a voltage value of one or more (e.g., each) of a plurality of battery cells charged under the same charging conditions, calculate a threshold value based on the voltage values of the plurality of battery cells at a preset SOC, and compare the voltage values of one or more (e.g., each) of the plurality of battery cells at the preset SOC with the threshold value, thereby controlling at least a part of an operation of detecting the battery cell with a welding defect.

In some embodiments, an example in which the processor 510 operates is the same as described above with reference to FIGS. 1 to 4. Therefore, a detailed description of the operation of the processor 510 will be omitted below.

The processor 510 may be implemented using at least one of application specific integrated circuits (ASICs), digital signal processors (DSPs), digital signal processing devices (DSPDs), programmable logic devices (PLDs), field programmable gate arrays (FPGAs), controllers, micro-controllers, microprocessors, and other electrical units for performing functions.

In an embodiment, the detection apparatus 500 may be a mobile electronic device. For example, the detection apparatus 500 may be implemented as a smartphone, a tablet PC, a PC, a smart TV, a personal digital assistant (PDA), a laptop, a media player, a navigation device, a camera-equipped device, and other mobile electronic devices. In some embodiments, the detection apparatus 500 may be implemented as a wearable device, such as a watch, glasses, hair band, or ring equipped with communication functions and data processing functions.

In some embodiments, the detection apparatus 500 may be an electronic device embedded in a secondary battery manufacturing facility. For example, the detection apparatus 500 may be an electronic device that is inserted into a secondary battery manufacturing facility through tuning after a production process.

In some embodiments, the detection apparatus 500 may be a server located outside the secondary battery manufacturing facility. The server may be implemented as a computer device or a plurality of computer devices that communicate over a network to provide commands, codes, files, content, services, etc.

In some embodiments, the process performed in the detection apparatus 500 may be performed by at least some of a mobile electronic device, an electronic device embedded within a secondary battery manufacturing facility, and a server located outside the secondary battery manufacturing facility.

According to the embodiments of the disclosure described above, a battery cell with a possibility of a welding defect may be detected without having a separate detection operation for detecting a battery cell with a welding defect, thereby improving the efficiency of the manufacturing process of a secondary battery.

An embodiment according to the disclosure may be implemented in the form of a computer program that may be executed through various components on a computer, and such a computer program may be recorded on a computer-readable medium. In some embodiments, the medium may include magnetic mediums, such as hard disks, floppy disks, and magnetic tapes, optical recording mediums, such as CD-ROMs and DVDs, magneto-optical mediums, such as floptical disks, and hardware devices specifically configured to store and execute program instructions, such as ROM, RAM, and flash memory.

In some embodiments, the computer program may be specially designed and configured for the disclosure or may be known and available to those skilled in the art in the computer software field. Examples of computer programs may include not only machine language code, such as that produced by a compiler, but also high-level language code that may be executed by a computer using an interpreter or the like.

According to an embodiment, a method according to various embodiments of the disclosure may be provided as included in a computer program product. Computer 1 program products may be traded between sellers and buyers as commodities. The computer program product may be distributed in the form of a machine-readable storage medium (e.g., compact disc read only memory (CD-ROM)) or may be distributed online (e.g., by download or upload), via an application store (e.g., Play Store™) or directly between two user devices. In the case of online distribution, at least a portion of the computer program product may be temporarily stored or temporarily created in a machine-readable storage medium, such as a memory of a server of a manufacturer, a server of an application store, or an intermediary server.

Unless there is an explicit description or contradiction of the order of the operations constituting the method according to the disclosure, the operations may be performed in any suitable order. The disclosure is not necessarily limited to the order in which the above operations are described. Any use of examples or terms in the disclosure is merely intended to illustrate the disclosure in more detail and is not intended to limit the scope of the disclosure due to such examples or terms, unless otherwise limited by the claims. Furthermore, those skilled in the art will appreciate that various modifications, combinations and variations may be made according to design conditions and factors within the scope of the appended claims or their equivalents.

Therefore, the idea of the disclosure should not be limited to the embodiments described above, and not only the scope of the patent claims described below but also all scopes equivalent to or equivalently modified from the scope of the patent claims are included in the scope of the idea of the disclosure.

What is claimed is:

1. A method for detecting a battery cell with a welding defect, the method comprising:
obtaining a voltage value of each of a plurality of battery cells charged under a selected charging condition;
calculating a threshold value based on the voltage values of the plurality of battery cells at an identified state of charge (SOC); and
detecting a battery cell of the plurality of battery cells with a welding defect by comparing the voltage value of one or more of the plurality of battery cells at the identified SOC with the threshold value.

2. The method of claim 1, wherein the identified SOC is set based on user input.

3. The method of claim 1, wherein the calculating of the threshold value includes calculating the threshold value based on a statistical value of the voltage values of the plurality of battery cells at the identified SOC.

4. The method of claim 3, wherein the statistical value includes at least one of a mean, median, variance, standard deviation, or quartile of the voltage values of the plurality of battery cells.

5. The method of claim 1,
wherein the calculating of the threshold value includes calculating the threshold value based on a statistical value of the plurality of battery cells at the identified SOC and based on a sensitivity factor, and
the sensitivity factor is set based on user input.

6. The method of claim 1, wherein the detecting of the battery cell with a welding defect includes detecting a battery cell having corresponding voltage value at the identified SOC that exceeds the threshold value.

7. The method of claim 1, wherein
the calculating of the threshold value includes:
calculating a first threshold value based on first ones of the voltage values of the plurality of battery cells at a first SOC; and
calculating a second threshold value based on second ones of the voltage values of the plurality of battery cells at a second SOC, and
the detecting of the battery cell with a welding defect includes:
identifying the battery cell with the welding defect based on a corresponding voltage value of each of the plurality of battery cells at the first SOC, the first threshold value, a corresponding voltage value of each of the plurality of battery cells at the second SOC, and the second threshold value.

8. The method of claim 7, wherein
the detecting of the battery cell with a welding defect includes:
identifying the battery cell having a corresponding voltage value at the first SOC that is less than or equal to the first threshold value and a corresponding voltage value at the second SOC that exceeds the second threshold value.

9. The method of claim 7, wherein
the first SOC and the second SOC are set based on user input.

10. The method of claim 1, wherein
the calculating of the threshold value is performed independently for each battery tray including a preset number of battery cells.

11. The method of claim 1, wherein
the detecting of the battery cell with the welding defect includes:
selecting one of the plurality of battery cells having a corresponding voltage value at the identified SOC that exceeds the threshold value as a candidate cell of a welding defect;
obtaining a weld image of the candidate cell of the welding defect; and
identifying the battery cell based on information included in the weld image.

12. The method of claim 1, wherein
the detecting of the battery cell with a welding defect includes:
selecting one of the plurality of battery cells having a corresponding voltage value at the identified SOC that exceeds the threshold value as a candidate cell of the welding defect; and
identifying the battery cell with the welding defect, based on a direct-current resistance value of the candidate cell of the welding defect calculated based on a direct-current current value applied to the candidate cell of the welding defect.

13. The method of claim 1, wherein
the detecting of the battery cell with the welding defect includes:
selecting one of the plurality of battery cells having a corresponding voltage value at the identified SOC that exceeds the threshold value as a candidate cell of the welding defect; and
identifying the battery cell with the welding defect based on an alternating-current impedance value of the candidate cell of the welding defect calculated based on an alternating-current current value applied to the candidate cell of the welding defect.

14. A computer-readable recording medium recorded thereon a program for causing a computer to execute the method of claim 1.

15. An apparatus for detecting a battery cell with a welding defect, the apparatus comprising:
a memory in which at least one program is stored; and
a processor operating by executing the at least one program, wherein the processor is configured to:
obtain a voltage value of each of a plurality of battery cells charged under a selected charging condition;
calculate a threshold value based on the voltage values of the plurality of battery cells at an identified state of charge (SOC); and
compare the voltage value of one or more of the plurality of battery cells at the identified SOC with the threshold value.

16. The apparatus of claim 15, wherein
the processor is further configured to calculate the threshold value based on a statistical value of the voltage values of the plurality of battery cells at the identified SOC.

17. The apparatus of claim 15, wherein
the processor is further configured to calculate a first threshold value based on first ones of the voltage values of the plurality of battery cells at a first SOC and a second threshold value based on second ones of the voltage values of the plurality of battery cells at a second SOC, and
the processor is further configured to detect the battery cell with the welding defect based on a corresponding voltage value of each of the plurality of battery cells at the first SOC, the first threshold value, a corresponding voltage value of each of the plurality of battery cells at the second SOC, and the second threshold value.

18. The apparatus of claim 17, wherein
the processor is further configured to identify the battery cell having a corresponding voltage value at the first SOC that is less than or equal to the first threshold value and a corresponding voltage value at the second SOC that exceeds the second threshold value, as the battery cell with the welding defect.

19. The apparatus of claim 15, wherein
the processor is further configured to:
select one of the plurality of battery cells having a corresponding voltage value at the identified SOC that exceeds the threshold value as a candidate cell of a welding defect;
obtain a weld image of the candidate cell of the welding defect, and
identifying the battery cell with the welding defect based on information included in the weld image.

20. The apparatus of claim 15, wherein
the processor is further configured to:
select one of the plurality of battery cells having a corresponding voltage value at the identified SOC that exceeds the threshold value as a candidate cell of the welding defect; and
identifying the battery cell with the welding defect, based on a direct-current resistance value of the candidate cell of the welding defect calculated based on a direct-current current value applied to the candidate cell of a welding defect.
